(19) United States
(12) Patent Application Publication
(10) Pub. No.: US 2010/0165456 A1
(43) Pub. Date: Jul. 1, 2010

(54) FILTER FOR PLASMA DISPLAY

(75) Inventors: Jinyoung LEE, Yongin-si (KR); Sungyong Lee, Yongin-si (KR); Jaehyung Kim, Yongin-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/624,502

(22) Filed: Nov. 24, 2009

(30) Foreign Application Priority Data
Dec. 30, 2008 (KR) 10-2008-0136961

(51) Int. Cl. G02B 5/20; H05K 9/00

(52) U.S. Cl. 359/359; 359/893; 361/818; 359/890

(57) ABSTRACT

A filter for a plasma display includes: a transparent substrate having a first surface and a second surface opposite to the first surface; a first external light shielding layer having a first pattern disposed on the first surface of the transparent substrate and having a mesh structure to shield electromagnetic waves and external light and a filter layer covering the first pattern and the first surface of the transparent substrate; a second external light shielding layer having a second pattern corresponding to the first pattern and formed on the filter layer to shield external light and an overcoating layer covering the second pattern and the filter layer; and a third external light shielding layer having a third pattern corresponding to the second pattern and formed on the overcoating layer to shield external light and a hard coating layer covering the third pattern to protect the third pattern.

### CROSS-REFERENCE TO RELATED APPLICATIONS

This application claims the benefit of Korean Patent Application No. 2008-136961, filed on Dec. 30, 2008, the disclosure of which is incorporated herein by reference.

### BACKGROUND OF THE INVENTION

1. Field of the Invention

Aspects of the present invention relate to a filter for a plasma display, and more particularly, to a filter for a plasma display that can reduce the thickness thereof, can become an integrated complex filter, and can be made thinner.

2. Description of the Related Art

A conventional filter for a plasma display typically includes an electromagnetic wave shielding film, an external light shielding film, a near-infrared ray shielding film, and a color correcting film that are laminated or bonded to be integrated thereby.

Black barriers are disposed in the external light shielding film and are spaced apart from each other by an interval so as to coincide with the horizontal side of a panel screen so that the external light shielding film can interrupt light introduced from the outside.

The external light shielding film can provide a high bright room contrast ratio by having a thickness of several hundred micrometers (μm) so that the black barriers can interrupt light that is introduced at greater than a specific angle. In other words, since the bright room contrast ratio is lower when the thickness of the external light shielding film is thin, it is desirable to make the entire filter thick.

Such an external light shielding film is generally formed by forming black barriers and filling a transparent polymer layer in a space between the black barriers or by forming a recess in a transparent polymer layer and filling black barriers in the recess. However, when the external light shielding film is thick, there is a difficulty in forming black barriers and filling in with a polymer layer or filling black barriers in a recess of a polymer layer.

In addition, since the external light shielding film is formed with one layer, a designed specification cannot be easily changed. Furthermore, when a design is changed, the external light shielding film may need to be developed in correspondence to a device to which it is applied.

### SUMMARY OF THE INVENTION

Aspects of the present invention provide a filter for a plasma display that can be integrated with a panel of the plasma display by forming the filter in a substrate of the panel. Accordingly, the plasma display can be made thinner by forming the filter as a complex filter including a color correction layer and a near-infrared ray layer in a filter layer or in an overcoating layer.

Aspects of the present invention reduce manufacturing costs of a plasma display by providing a filter for the plasma display that can be manufactured by stacking thin multiple external light shielding layers such that a laminating process and a formation of a bonding layer are not required.

Aspects of the present invention also provide a filter for a plasma display that can improve the bright room contrast ratio of the thin filter by providing multiple external light shielding layers.

In accordance with an embodiment of the present invention, there is provided a filter for a plasma display comprising: a transparent substrate having a first surface and a second surface opposite to the first surface; a first external light shielding layer having a first pattern disposed on the first surface of the transparent substrate and having a mesh structure to shield electromagnetic waves and external light and a filter layer covering the first pattern and the first surface of the transparent substrate; a second external light shielding layer having a second pattern corresponding to the first pattern and formed on the filter layer to shield external light and an overcoating layer covering the second pattern and the filter layer; and a third external light shielding layer having a third pattern corresponding to the second pattern and formed on the overcoating layer to shield external light and a hard coating layer covering the entire third pattern to protect the third pattern.

According to an aspect of the present invention, the first pattern may have a mesh structure in which a plurality of horizontal lines extending horizontally and spaced apart from each other and a plurality of vertical lines extending vertically and spaced apart from each other cross each other.

According to an aspect of the present invention, the second pattern and the third pattern may be arranged horizontally to correspond to the horizontal lines of the first pattern, may be arranged vertically to correspond to the vertical lines of the first pattern, or may be arranged both horizontally and vertically to correspond to the mesh structure of the first pattern.

According to an aspect of the present invention, the horizontal lines of the first pattern may have a pitch of 50 to 500 μm and the vertical lines of the first pattern may have a pitch of 100 to 1000 μm.

According to an aspect of the present invention, the filter layer may be a color correcting and near-infrared ray shielding layer.

According to an aspect of the present invention, the second external light shielding layer may have one to seven layers each having the second pattern and the overcoating layer. When the second external light shielding layer has multiple layers, the second patterns and the overcoating layers may be alternately formed.

According to an aspect of the present invention, the first pattern may comprise a mixture of a black material including carbon black, cobalt oxide, or ruthenium oxide, or an equivalent thereof and a conductive material comprising copper (Cu), silver (Ag), gold (Au), nickel (Ni), aluminum (Al), or ruthenium (Ru), or an equivalent thereof.

According to an aspect of the present invention, the second pattern and the third pattern may be made of a conductive material and a black material comprising carbon black, cobalt oxide, or ruthenium oxide, or an equivalent thereof.

According to an aspect of the present invention, the second pattern and the third pattern may include a conductive material to interrupt electromagnetic waves.

According to an aspect of the present invention, the overcoating layer may include a near-infrared ray shielding and color correcting dye to correct color and interrupt near-infrared rays.

According to an aspect of the present invention, the first pattern, the second pattern, and the third pattern may each comprise lines having a thickness of 2 to 10 μm and the widths of the first pattern, the second pattern, and the third pattern may be 10 to 50 μm.

According to an aspect of the present invention, the hard coating layer may comprise hardened material that has a reflection preventing function and an antifouling function.

According to an aspect of the present invention, the filter layer and the overcoating layer may each have a thickness of 10 to 50 μm.

According to an aspect of the present invention, the hard coating layer may have a thickness of 10 to 20 μm.

In accordance with another embodiment of the present invention, there is provided a filter for a plasma display comprising: a transparent substrate having a first surface and a second surface opposite to the first surface; a first external light shielding layer having a first pattern disposed on the first surface of the transparent substrate and having a mesh structure to shield electromagnetic waves and external light and a filter layer covering the first pattern and the first surface of the transparent substrate; and a second external light shielding layer having a second pattern corresponding to the first pattern and formed on the filter layer to shield external light and an overcoating layer covering the second pattern and the filter layer.

According to an aspect of the present invention, the first pattern may have a mesh structure in which a plurality of horizontal lines extending horizontally and spaced apart from each other and a plurality of vertical lines extending vertically and spaced apart from each other cross each other.

According to an aspect of the present invention, the second pattern may be arranged horizontally to correspond to the horizontal lines of the first pattern, may be arranged vertically to correspond to the vertical lines of the first pattern, or may be arranged both horizontally and vertically to correspond to the mesh structure of the first pattern.

According to another embodiment of the present invention, there is provided a plasma display comprising a plasma display panel; and a filter disposed on the plasma display panel, the filter comprising a first external light shielding layer having a first pattern disposed on a surface of the plasma display panel and having a mesh structure to shield electromagnetic waves and external light and a filter layer covering the first pattern and the surface of the plasma display panel; a second external light shielding layer having a second pattern corresponding to the first pattern and formed on the filter layer to shield external light and an overcoating layer covering the second pattern and the filter layer; and a third external light shielding layer having a third pattern corresponding to the second pattern and formed on the overcoating layer to shield external light and a hard coating layer covering the third pattern to protect the third pattern.

According to another embodiment of the present invention, there is provided a plasma display comprising: a plasma display panel; and a filter disposed on the plasma display panel, the filter comprising a first external light shielding layer having a first pattern disposed on a surface of the plasma display panel and having a mesh structure to shield electromagnetic waves and external light and a filter layer covering the first pattern and the surface of the plasma display panel; and a second external light shielding layer having a second pattern corresponding to the first pattern and formed on the filter layer to shield external light and an overcoating layer covering the second pattern and the filter layer.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A to 1D are a perspective view, a sectional view, and plan views of a filter for a plasma display according to an embodiment of the present invention;

FIG. 2A to 2B are a perspective view and a sectional view of a filter for a plasma display according to another embodiment of the present invention;

FIG. 3 is a flowchart illustrating a fabricating method for a filter for a plasma display of FIGS. 1A to 1D; and

FIGS. 4A to 4G are perspective views illustrating the fabricating method for a filter for a plasma display of FIG. 3.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

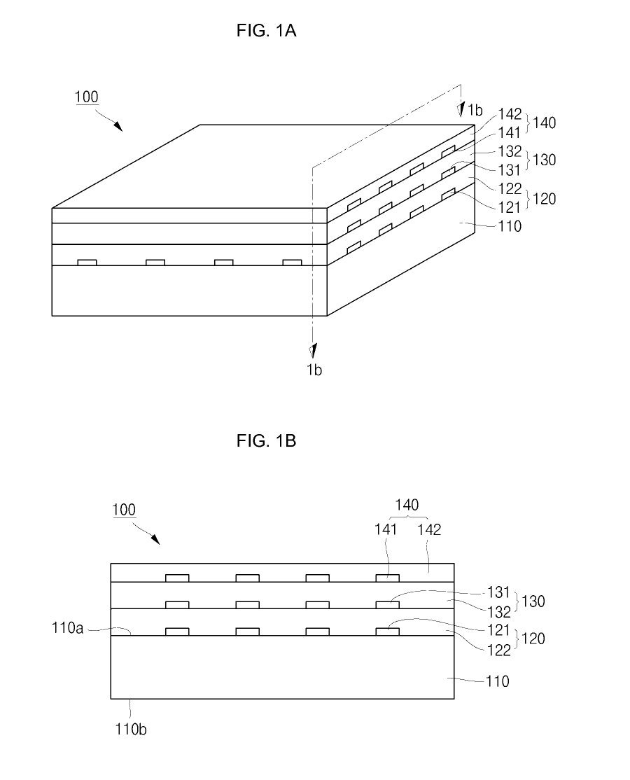

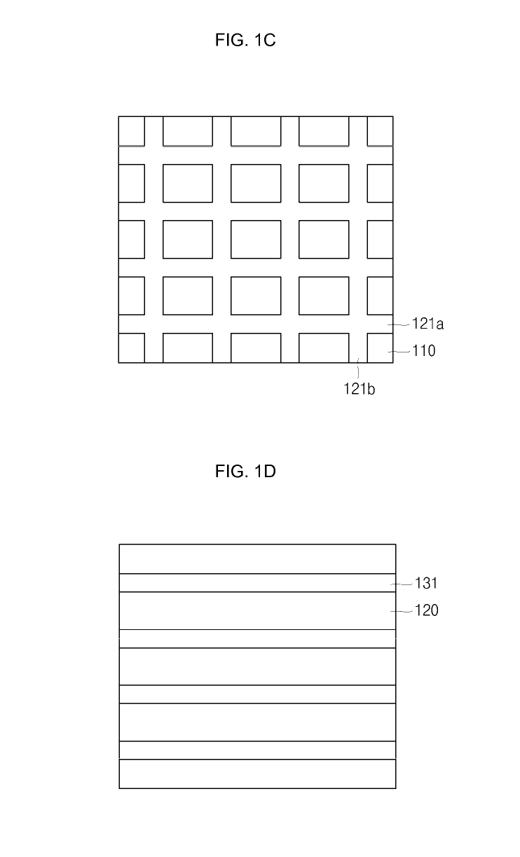

FIG. 1A is a perspective view illustrating a filter for a plasma display according to an embodiment of the present invention. FIG. 1B is a sectional view taken along line 1b-1b of FIG. 1A. FIG. 1C is a plan view illustrating a first pattern formed in the filter of FIG. 1A. FIG. 1D is a plan view illustrating a second pattern formed in the filter of FIG. 1A.

As illustrated in FIG. 1A to 1D, the filter 100 for a plasma display includes a transparent substrate 110, a first external light shielding layer 120, a second external light shielding layer 130, and a third external light shielding layer 140.

The transparent substrate 110 has a first flat surface 110a and a second surface 110b opposite to the first surface 110a. The transparent substrate 110 may be made of reinforced glass, general glass, or an equivalent thereof, but the present invention is not limited thereto. When a plasma display panel (hereinafter, referred to as “panel”) is used as the transparent substrate 110, a filter can be directly provided on a surface of the panel, the panel can made thinner.

The first external light shielding layer 120 is interposed between the first surface 110a of the transparent substrate 110 and the second external light shielding layer 130. The first external light shielding layer 120 includes a first pattern 121 and a filter layer 122. The first pattern 121 has a mesh structure so that electromagnetic waves and external light can be shielded from the first surface 110a of the transparent substrate 110. The filter layer 122 covers all of the first surface 110a of the transparent substrate 110.

The first pattern 121 has horizontal lines 121a extending horizontally and vertical lines 121b extending vertically. As used herein, the terms “horizontal lines” and “vertical lines” refer to the orientation of these features when the plasma display panel is in a conventional viewing position, with horizontal lines extending in a direction across the panel from one side to the other from the perspective of a viewer and with vertical lines extending in an up and down direction across the panel from the perspective of the viewer. The term “arranged horizontally” with respect to a pattern refers to lines of the pattern extending in a horizontal direction and being spaced apart in a vertical direction. Similarly, the term “arranged vertically” refers to lines of the pattern extending in a vertical direction and being spaced apart in a horizontal direction. In either case, the term “arranged” is used to describe the location of lines and is not meant to be limiting regarding any particular fabrication process. As used herein, the term “thickness” of pattern lines refers to a measurement in a direction perpendicular to the substrate. The term “width” with respect to pattern lines refers to a measurement in a direction parallel to the substrate and perpendicular to the direction of the line. For example, the width of a horizontal line is measured in a vertical direction and the width of vertical line is measured in a horizontal direction. The term “pitch” with respect to pattern lines refers to a measurement of the spacing of pattern lines extending in the same direction. The horizontal lines 121a and the vertical lines 121b cross each other to form a mesh structure. The horizontal lines 121a of the first pattern 121 shield electromagnetic waves and absorb and interrupt external light introduced into the panel from the outside. The vertical lines 121b shield electromagnetic waves. As a non-limiting example, the first pattern 121 may be black to absorb external light and may be made of a conductive material to interrupt electromagnetic waves. The first pattern 121 may be a mixture of a conductive material such as copper (Cu), silver (Ag), gold (Au), nickel (Ni), aluminum (Al), ruthenium (Ru), or an equivalent thereof and a black material such as carbon black, cobalt oxide, ruthenium oxide, or one of their equivalents.

The thickness of the first pattern 121 may be 2 to 10 μm. When the thickness of the first pattern 121 is less than 2 μm, it may be difficult to properly shield external light and electromagnetic waves. On the other hand, when the thickness of the first pattern 121 exceeds 10 μm the overall thickness of the filter 100 for a plasma display become thicker, degrading the quality of the display.

The width of the horizontal lines 121a and the vertical lines 121b of the first pattern 121 may be 5 to 50 μm. When the width of the horizontal lines 121a and the vertical lines 121b of the first pattern 121 is less than 5 μm, the range of angles in which external light and electromagnetic waves are interrupted is reduced, making it difficult to properly shield external light and electromagnetic waves. On the other hand, when the width of the horizontal lines 121a and the vertical lines 121b of the first pattern 121 exceed 50 μm, the first pattern 121 becomes visually apparent to a viewer, degrading the quality of the display.

The pitch between the horizontal lines 121a of the first pattern 121 may be 50 to 500 μm, and the pitch between the vertical lines 121b may be 100 to 1000 μm. When the pitch between the horizontal lines 121a of the first pattern 121 is below 50 μm, it may be difficult to secure a sufficient opening rate for the display. On the other hand, when the pitch between the horizontal lines 121a exceeds 500 μm, it may be difficult for the display to properly interrupt magnetic waves and external light. In addition, when the pitch between the vertical lines 121b of the first pattern 121 is below 100 μm, it may be difficult to secure a sufficient opening rate for display. On the other hand, when the pitch between the vertical lines 121b exceeds 1000 μm, it is difficult to secure shielding from electromagnetic waves.

Although the first pattern 121 is shown as having four horizontal lines 121a and four vertical lines 121b in FIGS. 1A to 1C, the present invention is not limited thereto. In other words, the first pattern 121 may have a plurality of horizontal lines 121a and a plurality of vertical lines 121b that correspond to the thickness, width, and pitch of the first pattern 121 according to the size of the panel. Moreover, it is to be understood that the first pattern 121 is not limited to horizontal and vertical lines, but may be made up of any form of intersecting lines that form a mesh.

The filter layer 122 covers all of the transparent substrate 110 and the first pattern 121. The filter layer 122 serves to correct colors and to shield near-infrared rays. The filter layer 122 can interrupt not only waves of 700 to 1200 nanometers (nm) (near-infrared rays) but also waves of 380 to 780 nm (visible rays).

The filter layer 122 may lower the transmission rate in the 700 to 1200 nanometer wave region to below 20 percent to shield near-infrared rays, and may lower the transmission rate in the 380 to 780 nanometer wave region to 5 to 90 percent in order to provide color correction.

The filter layer 122 is formed by coating a color correcting and near-infrared ray shielding agent obtained by mixing a thermosetting resin and a solvent with a near-infrared ray shielding and color correcting dye onto the first pattern 121 and the first surface 110a of the transparent substrate 110 so that the color correcting and near-infrared ray shielding agent covers all the first pattern 121 and the first surface 110a of the transparent substrate 110. In other words, the filter layer 122 is formed by mixing a thermosetting resin with the near-infrared ray shielding and color correcting dye. The filter layer 122 may further include a thermosetting agent that promotes the thermosetting of the filter layer 122 and a leveling agent to make the surface of the filter layer 122 uniform, but the present invention is not limited thereto.

The thermosetting resin may be a phenol resin, a urea resin, or a melamine resin, but the present invention is not limited thereto. Alternatively, the filter layer 122 may comprise an addition polymerization resin, which may be one selected from an epoxy resin, a polyester resin, an unsaturated polyester resin, a multifunctional acrylate resin, an epoxy acrylate resin, and their equivalents or a mixture of them.

The color correcting dye may be one selected from an anthraquinone series dye, a cyanine series dye, an azo series dye, a styryl series dye, a naphthalocyanine series dye, and a methine series dye or a mixture of these, but the present invention is not limited thereto.

The near-infrared ray shielding dye may be one selected from a phthalocyanine series dye, a naphthalocyanine series dye, an anthraquinone series dye, a naphthoquinone series dye, a cyanine series dye, a metal complex series dye, an ammonium series dye, an aluminum series dye, an immonium series dye, a diimmonium series dye, a polymethine series dye, an aromatic dithiol series dye, an aromatic diol series dye or a mixture of these, but the present invention is not limited thereto.

The thickness of the filter layer 122 may be 10 to 50 μm. When the thickness of the filter layer is less than 10 μm, the near-infrared ray shielding and color correcting function may be so weak that peripheral devices may malfunction due to the near-infrared rays irradiated from the display. On the other hand, when the thickness of the filter layer exceeds 50 micrometers, the luminance of display can be lowered, causing visibility to deteriorate.

The second external light shielding layer 130 is interposed between the filter layer 122 of the first external light shielding layer 120 and the third external light shielding layer 140. The second external light shielding layer 131 includes a second pattern 131 and an overcoating layer 132. The second pattern 131 is formed on the filter layer 122 to correspond to the first pattern 121 to shield external light thereby. The overcoating layer 132 covers all of the second pattern 131 and the filter layer 122.

As used herein, terms such as “in correspondence with” or “correspond to” with respect to patterns or lines of the shielding layers refer generally to the patterns or lines of respective layers being in alignment in a direction perpendicular to the filter layers. For example, if the filter 100 were viewed from a direction perpendicular to the filter layers, the lines of respective shielding layers that are in correspondence with each other would appear to be in the same location. Herein, a second or third pattern may correspond to a first pattern even if the second or third pattern does not have all the features of the first pattern. For example, a second or third pattern may correspond to a first pattern in the form of a mesh even if the second or third pattern includes only horizontal lines or only vertical lines, as long as the horizontal lines or vertical lines of the second or third pattern line up with the horizontal or vertical mesh lines of the first pattern. Also, herein, it is to be understood that where is stated herein that one layer is “formed on” or “disposed on” a second layer, the first layer may be formed or disposed directly on the second layer or there may be intervening layers between the first layer and the second layer. Also, as used herein, the term “formed on” is used with the same meaning as “located on” or “disposed on” and is not meant to be limiting regarding any particular fabrication process.

The second pattern 131 may be formed to correspond to the horizontal lines 121a extending in the horizontal direction of the first pattern 121, the vertical lines 121b extending in the vertical direction of the first pattern 121, or the mesh structure of the first pattern 121. Since the second pattern 131 is formed to shield external light, the second pattern 131 may comprise horizontal lines that correspond to the horizontal lines 121a of the first pattern 121.

The second pattern 131 may be black to absorb external light, and may be mixed with a conductive material to additionally increase the electromagnetic wave shielding effect. The second pattern 131 may be made of a black material such as carbon black, cobalt oxide, ruthenium oxide, or their equivalents and may be mixed with a conductive material such as copper (Cu), silver (Ag), gold (Au), nickel (Ni), aluminum (Al), ruthenium (Ru), or their equivalents, but the present invention is not limited thereto.

The thickness of the second pattern 131 may be 2 to 10 μm. When the thickness of the second pattern 131 is less than 2 μm, it may be difficult to properly shield external light. On the other hand, when the thickness of the second pattern 131 exceeds 10 μm, the overall thickness of the filter 100 becomes greater, degrading the quality of display.

The width of the second pattern 131 may be 10 to 50 μm. When the width of the second pattern 131 is less than 10 μm, the range of angles in which external light and electromagnetic waves are interrupted is reduced, making it difficult to properly shield external light. On the other hand, when the width of the second pattern 131 exceeds 50 μm, the second pattern 131 becomes visible, degrading the quality of display.

The second pattern 131 may have the same pitch as that of the first pattern 121.

The overcoating layer 132 covers all of the second pattern 131 and the filter layer 122 to protect the second pattern 131 thereby. The overcoating layer 132 has a transmission rate of 80 percent to transmit internal light to the outside and may have a refraction rate of 1 to 1.6. A near-infrared ray shielding dye and a color correcting dye are mixed with each other in the overcoating layer 132 to effectively shield near-infrared rays of the filter for a plasma display and increase the color correcting effect.

The thickness of the overcoating layer 132 may be 10 to 50 μm. When the thickness of the overcoating layer 132 is less than 10 micrometers, the overcoating layer 132 does not cover all of the second pattern 131, making it difficult to substantially protect the second pattern 131. On the other hand, when the thickness of the overcoating layer 132 exceeds 50 μm, the luminance of the display is lowered, degrading the visibility.

The second external light shielding layer 130 may include 1 to 7 separate layers, each including the second pattern 131 and the overcoating layer 132. When the second external light shielding layer 130 has multiple layers, the second pattern 131 and the overcoating layer 132 are alternately stacked.

If the second external light shielding layer 130 has more than 7 layers, the process of forming the filter becomes complicated, increasing costs.

The third external light shielding layer 140 covers all of the overcoating layer of the second external shielding layer 130. The third external light shielding layer 140 includes a third pattern 141 and a hard coating layer 142. The third pattern 141 is formed in the overcoating layer 132 to correspond to the second pattern 131 to shield external light. The hard coating layer 142 covers all of the third pattern 141 and the overcoating layer 132.

The third pattern 141 may be formed to correspond to the horizontal lines 121a extending in the horizontal direction of the first pattern 121, the vertical lines 121b extending in the vertical direction of the first pattern 121, or the mesh structure of the first pattern 121. Since the third pattern 141 is formed to shield external light, the third pattern may correspond to the horizontal lines 121a of the first pattern 121 and have the same pattern as the second pattern 131.

The third pattern 141 may be black to absorb external light, and may be mixed with a conductive material to additionally increase the electromagnetic wave shielding effect. The third pattern 141 may be made of a black material such as carbon black, cobalt oxide, ruthenium oxide, or an equivalent thereof and may be mixed with a conductive material such as copper (Cu), silver (Ag), gold (Au), nickel (Ni), aluminum (Al), ruthenium (Ru), or an equivalent thereof, but the present invention is not limited thereto.

The thickness of the third pattern 141 may be 2 to 10 μm. When the thickness of the third pattern 141 is below 2 μm, it may be difficult to properly shield external light. On the other hand, when the thickness of the third pattern 141 exceeds 10 μm, the third pattern 141 becomes visible, degrading the quality of display.

The width of the third pattern 141 may be 10 to 50 μm. When the width of the third pattern 141 is below 10 μm, the range of angles by which external light and electromagnetic waves are interrupted is reduced, making it difficult to properly shield external light. On the other hand, when the width of the third pattern 141 exceeds 50 μm, the third pattern 141 becomes visible, degrading the quality of display.

The third pattern 141 may have the same pitch as the pitch of the first pattern 121 and the second pattern 131.

The hard coating layer 142 covers all of the third pattern 141 and the overcoating layer 132 to protect the third pattern 141. The hard coating layer 142 also protects the filter 100 for a plasma display from an external impact and contamination. High refraction rate layers and low refraction rate layers may be sequentially stacked in the hard coating layer 142 so that the hard coating layer 142 has a reflection preventing function and an antifouling function, but the present invention is not limited thereto.

The thickness of the hard coating layer 142 may be 10 to 20 μm. When the thickness of the hard coating layer 142 is below 10 μm, the hard coating layer 142 may not sufficiently cover the third pattern 141, making it difficult to substantially protect the third pattern 141 and the filter 100 for a plasma display. On the other hand, when the thickness of the hard coating layer 142 exceeds 20 μm, the luminance of display is lowered, degrading the visibility of the plasma display.

The filter 100 for a plasma display is a complex filter having an external light shielding function, an electromagnetic wave shielding function, a near-infrared shielding function, a color correcting function, a reflection preventing function, and an antifouling function. Therefore, manufacturing costs can be reduced by making it unnecessary to laminate separate filters and create bonding layers.

In addition, the filter 100 for a plasma display forms a plurality of external light shielding layers and sequentially interrupts external light that is introduced into the patterns of the external light shielding layers. For example, when the second external light shielding layer 130 includes one layer, the third pattern 141 primarily shields external light, the second pattern 131 secondarily shields external light, and the first pattern 121 finally shields any external light that has passed through the third pattern 141 and the second pattern 131. The filter 100 for a plasma display increases the reflection luminance of the panel even when the filter 100 is thin, increasing the bright room contrast ratio.

Since the filter 100 for a plasma display includes a plurality of external light shielding layers, the filter 100 can be thinner than a conventional filter that uses a black barrier, maintaining the luminance and bright room contrast ratio of the panel. In this case, since the thickness of the filter 100 for a plasma display can be reduced, the filter 100 can be made thinner through integration of the panel and the filter.

Since the filter 100 for a plasma display includes a plurality of external light shielding layers, a black barrier can be easily filled in a recess of a thick polymer resin and a polymer resin can be filled after formation of a thick black barrier.

Since the filter 100 for a plasma display includes a plurality of external light shielding layers, the thickness of the filter 100 for a plasma display can be easily changed according to a design specification and different versions of the filter 100 for a plasma display can be formed using the same device.

The filter 100 for a plasma display can shield external light that is introduced at 30 to 90 degrees from a perpendicular direction with respect to the panel surface, and the bright room contrast ratio can be 900:1.

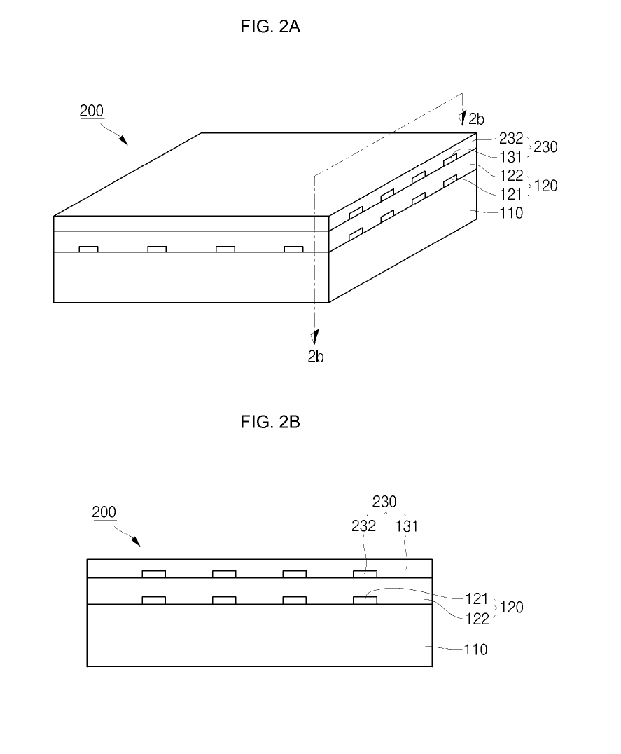

FIG. 2A is a perspective view illustrating a filter for a plasma display according to another embodiment of the present invention. FIG. 2B is a sectional view taken along line 2b-2b of FIG. 2A.

As illustrated in FIGS. 2A and 2B, the filter 200 for a plasma display includes a transparent substrate 110, a first external light shielding layer 120 having a first filter 121 and a filter layer 122, and a second external light shielding layer 230 having a second filter 131 and a hard coating layer 232. The transparent substrate 110, the first external light shielding layer 120, and the second filter 131 of the second external light shielding layer 130 of the filter 200 for a plasma display are the same as those of the filter 100 for a plasma display illustrated in FIGS. 1A to 1D. Hereinafter, the hard coating layer 232 of the second external light shielding layer 230 will be mainly described.

The hard coating layer 232 covers all of the second pattern 131 and the filter layer 122 to protect the second pattern 131, and further, to protect the filter 200 for a plasma display from an external impact and contamination. High refraction rate layers and low refraction rate layers may be sequentially stacked in the hard coating layer 232 so that the hard coating layer 232 has a reflection preventing function and an antifouling function, but the present invention is not limited thereto.

The thickness of the hard coating layer 232 may be 10 to 20 μm. When the thickness of the hard coating layer 232 is below 10 μm, the hard coating layer 232 may not sufficiently cover the second pattern 131, making it difficult to substantially protect the second pattern 131 and the filter 200 for a plasma display. On the other hand, when the thickness of the hard coating layer 232 exceeds 20 μm, the luminance of display is lowered, degrading the visibility of the plasma display.

The filter 200 for a plasma display is a complex filter having an external light shielding function, an electromagnetic wave shielding function, a near-infrared shielding function, a color correcting function, a reflection preventing function, and an antifouling function. Therefore, manufacturing costs can be reduced by making it unnecessary to laminate separate filters and create bonding layers.

In addition, the filter 200 for a plasma display forms a plurality of external light shielding layers and sequentially interrupts the external light introduced into the patterns of the external light shielding layers. The filter 200 for a plasma display increases the reflection luminance of the panel since the second pattern 131 primarily shields external light and the first pattern 121 secondarily shields external light.

Since the thickness of the filter 200 for a plasma display can be reduced, the filter can be made thinner through integration of the panel and the filter.

Since the filter 200 for a plasma display includes a plurality of external light shielding layers, a black barrier can be easily filled in a recess of a thick polymer resin and a polymer resin can be filled after formation of a thick black barrier.

Since the filter 200 for a plasma display includes a plurality of external light shielding layers, the thickness of the filter 200 for a plasma display can be easily changed according to a design specification and variations of the filter 200 for a plasma display can be formed using the same device.

The filter 200 for a plasma display can shield external light introduced at 40 to 60 degrees from a perpendicular direction with respect to the panel surface, and the bright room contrast ratio can be 700:1. When the external light shielding layers are dual layers, the range of angles in which external light that can be shielded is narrow as compared with the range of angles that is obtained with more than three layers, but the filter can be made thinner.

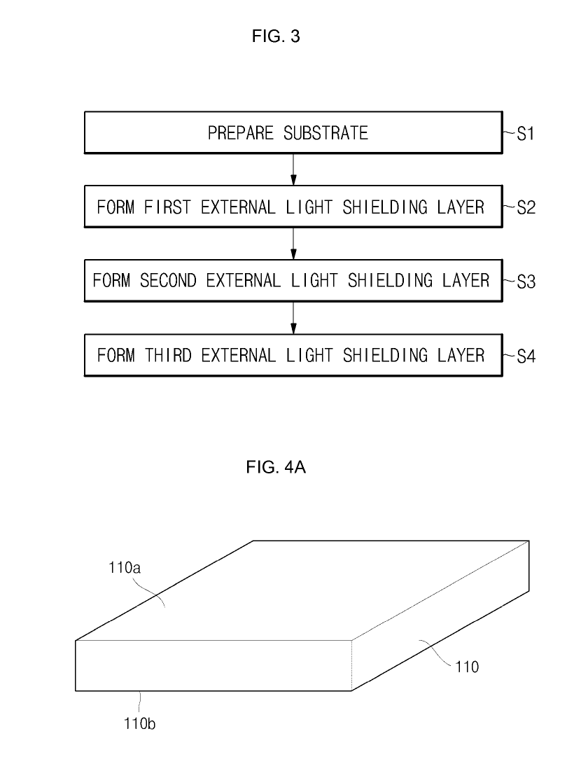

FIG. 3 is a flowchart illustrating a manufacturing method for the filter for the plasma display of FIGS. 1A to 1D.

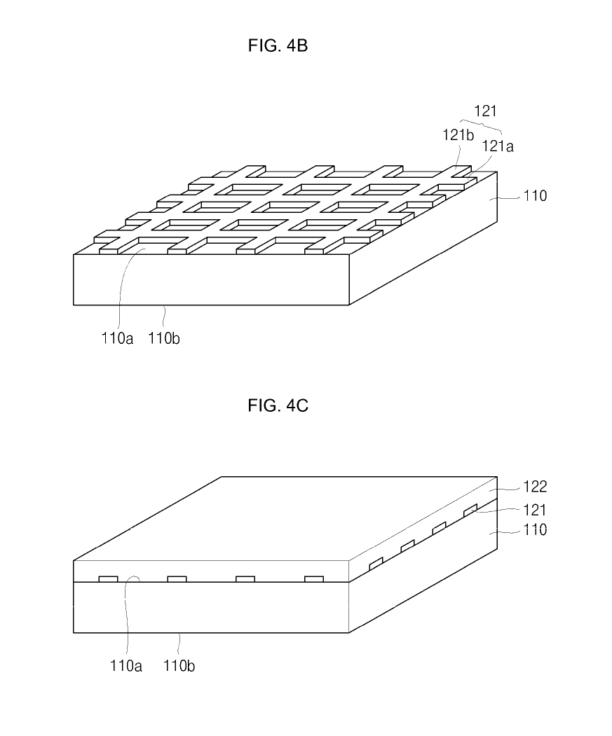

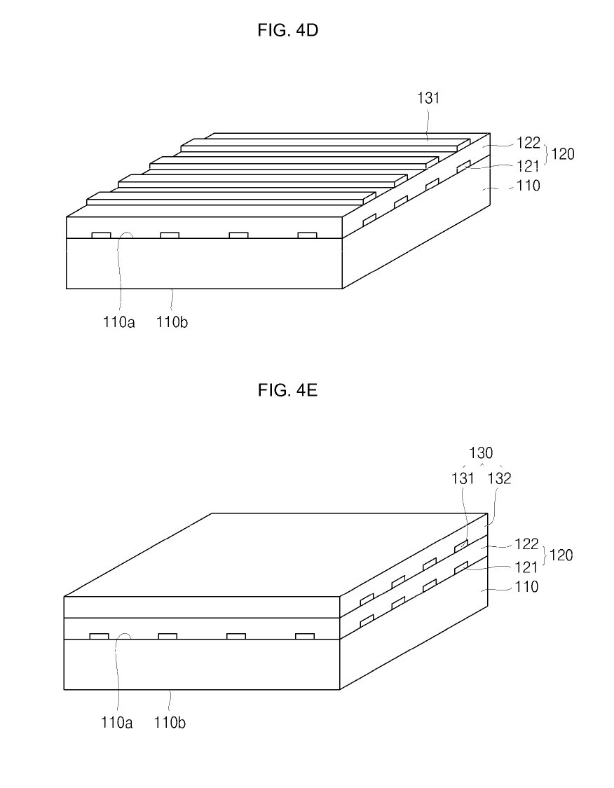

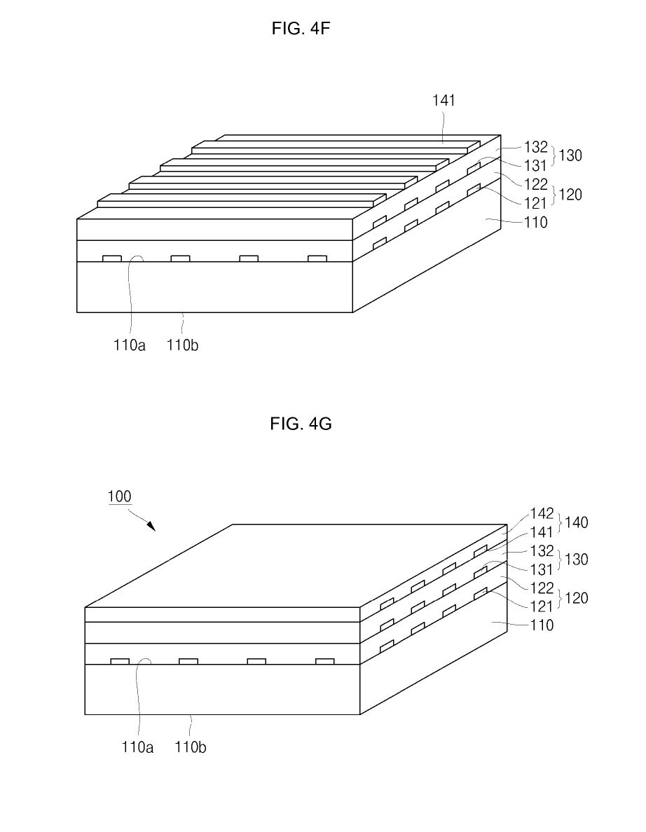

As illustrated in FIG. 3, the manufacturing method for a filter for a plasma display includes preparing a substrate (S1), forming a first external light shielding layer (S2), forming a second external light shielding layer (S3), and forming a third external light shielding layer (S4). The manufacturing method for a filter for a plasma display will be described in more detail with reference to FIGS. 4A to 4G.

FIGS. 4A to 4G are perspective views illustrating the manufacturing method for a filter for a plasma display of FIG. 3.

As illustrated in FIG. 4A, in the preparing of the substrate, a transparent substrate 110 having a first flat surface 110a and a second surface 110b opposite to the first surface 110a is prepared. When the transparent substrate 110 is a panel of the plasma display, the filter is directly formed on a surface of the panel, reducing the thickness of the panel and allowing the filter for a plasma display to be made thinner.

As illustrated in FIGS. 4B and 4C, in the forming of the first external light shielding layer, the first pattern 121 having a mesh structure is formed on the first surface 110a of the transparent substrate 110 and the filter layer 122 is formed to cover all of the first pattern 121 and the first surface of the transparent substrate 110.

The first pattern 121 has horizontal lines 121a extending horizontally and vertical lines 121b extending vertically. The horizontal lines 121a and the vertical lines 121b cross each other to form a mesh structure.

The first pattern 121 is made of a mixture of a black material that shields external light and a conductive material. The first pattern 121 may be formed by screen printing, offsetting, gravure printing, ink jetting, or an equivalent thereof, but the present invention is not limited thereto.

The first pattern 121 may be dried and baked after being formed so as to provide conductivity, but the present invention is not limited thereto.

The filter layer 122 may be formed by slit coating, tape casting, comma coating, spraying, or an equivalent thereof, but the present invention is not limited thereto.

The filter layer 122 may undergo thermosetting or UV thermosetting after being formed so as to harden the filter layer 122, but the present invention is not limited thereto.

As illustrated in FIGS. 4D to 4E, in the forming of the second external light shielding layer, the second pattern 131 is formed on the filter layer 122 to correspond with the first pattern 121, and the overcoating layer 132 is formed to cover all of the second pattern 131 and the filter layer 122.

The second pattern 131 may be formed to correspond to the horizontal lines 121a extending in the horizontal direction of the first pattern 121, the vertical lines 121b extending in the vertical direction of the first pattern 121, or the mesh structure of the first pattern 121.

The second pattern 131 is made of a black material for shielding external light. The black material may be mixed with a conductive material to shield electromagnetic waves. The second pattern 131 may be formed by screen printing, offsetting, gravure printing, ink jetting, or an equivalent thereof, but the present invention is not limited thereto.

The overcoating layer 132 may be formed by slit coating, tape casting, comma coating, spraying, or an equivalent thereof, but the present invention is not limited thereto.

The overcoating layer 132 may undergo thermosetting or UV thermosetting after being formed to harden the overcoating layer 132, but the present invention is not limited thereto.

As illustrated in FIGS. 4F to 4G, in the forming of the third external light shielding layer, the third pattern 141 is formed on the overcoating layer to correspond to the second pattern 131, and the hard coating layer 142 covers all of the third pattern 141 and the overcoating layer 132.

The third pattern 141 may be formed to correspond to the horizontal lines 121a extending in the horizontal direction of the first pattern 121, the vertical lines 121b extending in the vertical direction of the first pattern 121, or the mesh structure of the first pattern 121. Since the third pattern 141 is formed to shield external light, the third pattern may correspond to the horizontal lines 121a of the first pattern 121 and have the same pattern as the second pattern 131.

The third pattern 141 is made of a black material for shielding external light. The black material may be mixed with a conductive material to shield electromagnetic waves. The third pattern 141 may be formed by screen printing, offsetting, gravure printing, ink jetting, or an equivalent thereof, but the present invention is not limited thereto.

High refraction rate layers and low refraction rate layers are sequentially stacked in the hard coating layer 142 so that the hard coating layer 142 has a reflection preventing function and an antifouling function, but the present invention is not limited thereto. The hard coating layer 142 may be stacked by slit coating, tape casting, comma coating, spraying, or an equivalent thereof, but the present invention is not limited thereto.

The hard coating layer 142 may undergo thermosetting or UV thermosetting after being formed to harden the hard coating layer 132, but the present invention is not limited thereto.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A filter for a plasma display comprising:
a transparent substrate having a first surface and a second surface opposite to the first surface;
a first external light shielding layer having a first pattern disposed on the first surface of the transparent substrate and having a mesh structure to shield electromagnetic waves and external light and a filter layer covering the first pattern and the first surface of the transparent substrate;
a second external light shielding layer having a second pattern corresponding to the first pattern and formed on the filter layer to shield external light and an overcoating layer covering the second pattern and the filter layer; and
a third external light shielding layer having a third pattern corresponding to the second pattern and formed on the overcoating layer to shield external light and a hard coating layer covering the third pattern to protect the third pattern.

2. The filter for a plasma display of claim 1, wherein the first pattern has a mesh structure in which a plurality of horizontal lines extending horizontally and spaced apart from each other and a plurality of vertical lines extending vertically and spaced apart from each other cross each other.

3. The filter for a plasma display of claim 2, wherein the second pattern and the third pattern are arranged horizontally to correspond to the horizontal lines of the first pattern, are arranged vertically to correspond to the vertical lines of the first pattern, or are arranged both horizontally and vertically to correspond to the mesh structure of the first pattern.

4. The filter for a plasma display of claim 2, wherein the horizontal lines of the first pattern have a pitch of 50 to 500 μm and the vertical lines of the first pattern have a pitch of 100 to 1000 μm.

5. The filter for a plasma display of claim 1, wherein the filter layer is a color correcting and near-infrared ray shielding layer.

6. The filter for a plasma display of claim 1, wherein the second external light shielding layer has two to seven layers each having the second pattern and the overcoating layer and wherein the second patterns and the overcoating layers are alternately disposed.

7. The filter for a plasma display of claim 1, wherein the first pattern comprises a black material comprising carbon black, cobalt oxide, or ruthenium oxide, or an equivalent thereof and a conductive material comprising copper (Cu), silver (Ag), gold (Au), nickel (Ni), aluminum (Al), or ruthenium (Ru), or an equivalent thereof.

8. The filter for a plasma display of claim 1, wherein the second pattern and the third pattern are made of a conductive material and a black material comprising carbon black, cobalt oxide, or ruthenium oxide, or an equivalent thereof.

9. The filter for a plasma display of claim 8, wherein the conductive material included in the second pattern and the third pattern interrupts electromagnetic waves.

10. The filter for a plasma display of claim 1, wherein the overcoating layer includes a near-infrared ray shielding and color correcting dye that corrects color and interrupts near-infrared rays.

11. The filter for a plasma display of claim 1, wherein the first pattern, the second pattern, and the third pattern each comprise lines having a thickness of 2 to 10 μm and a width of 10 to 50 μm.

12. The filter for a plasma display of claim 1, wherein the hard coating layer includes hardened materials that prevent reflections and provide antifouling protection.

13. The filter for a plasma display of claim 1, wherein the filter layer and the overcoating layer each have a thickness of 10 to 50 μm.

14. The filter for a plasma display of claim 1, wherein the hard coating layer has a thickness of 10 to 20 μm.

15. The filter for a plasma display of claim 1, wherein:
the filter layer covers all of the first pattern and the first surface of the transparent substrate;
the overcoating layer covers all of the second pattern and the filter layer; and
the hard coating layer covers all of the third pattern and the overcoating layer.

16. The filter of claim 1, wherein the filter has an external light shielding function, an electromagnetic wave shielding function, a near-infrared shielding function, a color correcting function, a reflection preventing function and an antifouling function.

17. A filter for a plasma display comprising:
a transparent substrate having a first surface and a second surface opposite to the first surface;
a first external light shielding layer having a first pattern disposed on the first surface of the transparent substrate and having a mesh structure to shield electromagnetic waves and external light and a filter layer covering the first pattern and the first surface of the transparent substrate; and
a second external light shielding layer having a second pattern corresponding to the first pattern and formed on the filter layer to shield external light and an overcoating layer covering the second pattern and the filter layer.

18. The filter for a plasma display of claim 17, wherein the first pattern has a mesh structure in which a plurality of horizontal lines extending horizontally and spaced apart from each other and a plurality of vertical lines extending vertically and spaced apart from each other cross each other.

19. The filter for a plasma display of claim 18, wherein the second pattern is arranged horizontally to correspond to the horizontal lines of the first pattern, is arranged vertically to correspond to the vertical lines of the first pattern, or is arranged both horizontally and vertically to correspondence to the mesh structure of the first pattern.

20. The filter for a plasma display of claim 18, wherein:
the filter layer covers all of the first pattern and the first surface of the transparent substrate; and
the hard coating layer covers all of the second pattern and the filter layer.
